(19) United States
(12) Patent Application Publication
(10) Pub. No.: US 2019/0161886 A1
(43) Pub. Date: May 30, 2019

(54) SIC EPITAXIAL GROWTH APPARATUS

(71) Applicant: SHOWA DENKO K.K., Tokyo (JP)

(72) Inventors: Yasunori MOTOYAMA, Tokyo (JP); Yoshishige OKUNO, Chiba-shi (JP); Yoshikazu UMETA, Chichibu-shi (JP); Keisuke FUKADA, Chichibu-shi (JP)

(73) Assignee: SHOWA DENKO K.K., Tokyo (JP)

(21) Appl. No.: 16/196,212

(22) Filed: Nov. 20, 2018

(30) Foreign Application Priority Data
Nov. 24, 2017 (JP) 2017-225659

(51) Int. Cl. C30B 25/12; C30B 25/10; C30B 29/36; C23C 16/32; C23C 16/46; C23C 16/458

(52) U.S. Cl. CPC C30B 25/12; C30B 25/10; C23C 16/4583; C23C 16/325; C23C 16/46; C30B 29/36

(57) ABSTRACT

A SiC epitaxial growth apparatus includes: a susceptor having a mounting surface on which a wafer is placable; and a heater which is provided apart from the susceptor on a side opposite to the mounting surface of the susceptor, in which an unevenness is formed on a radiation-receiving surface of the susceptor, which faces a first surface of the heater provided at the susceptor side, and the unevenness is located at a position which is overlapped with an outer peripheral portion of the wafer placed on the susceptor in a plan view.

### BACKGROUND OF THE INVENTION

### Field of the Invention

The present invention relates to a SiC epitaxial growth apparatus.

Priority is claimed on Japanese Patent Application No. 2017-225659, filed on Nov. 24, 2017, the content of which is incorporated herein by reference.

### Description of Related Art

Silicon carbide (SiC) has characteristics such that the dielectric breakdown field is larger by one order of magnitude, the band gap is three times larger, and the thermal conductivity is approximately three times higher than those of silicon (Si). Therefore, application of silicon carbide (SiC) to power devices, high-frequency devices, high-temperature operation devices and the like is expected.

In order to promote the practical application of SiC devices, it is essential to establish high-quality SiC epitaxial wafers and high-quality epitaxial growth techniques.

The SiC device is fabricated by using a SiC epitaxial wafer in which an epitaxial layer (film), which is to become an active region of the device, is grown by a chemical vapor deposition (CVD) method or the like, on a SiC single crystal substrate, wherein the substrate is obtained by processing a bulk single crystal of SiC which is grown by a sublimation recrystallization method or the like. In this specification, a SiC epitaxial wafer means a wafer after an epitaxial film is formed, and a SiC wafer means a wafer before an epitaxial film is formed.

The epitaxial film of SiC grows at an extremely high temperature of about 1500° C. The growth temperature greatly affects the film thickness and properties of the epitaxial film. For example, in Patent Document 1, a semiconductor manufacturing apparatus is described which can uniformize the temperature distribution of a wafer during epitaxial growth due to a difference in thermal conductivity. In Patent Document 2, it is described that the temperature distribution of a wafer can be uniformized during epitaxial growth by supporting the wafer with a support element.

### PRIOR ART DOCUMENTS

### Patent Documents

Patent Document 1: Japanese Unexamined Patent Application, First Publication No. 2010-129764

Patent Document 2: Japanese Unexamined Patent Application, First Publication No. 2012-44030

### SUMMARY OF THE INVENTION

### Problems to be solved by the Invention

There have been attempts to increase the size of a SiC epitaxial wafer to six inches or more. In the manufacturing of such a large SiC epitaxial wafer, the semiconductor apparatuses described in Patent Document 1 and Patent Document 2 could not sufficiently suppress a temperature difference in a wafer in an in-plane direction.

The present invention has been made taking the foregoing problems into consideration, and an object thereof is to obtain a SiC epitaxial growth apparatus capable of uniformizing a temperature distribution during epitaxial growth.

### Means for Solving the Problem

As a result of intensive studies, the inventors found that the temperature of an outer peripheral portion of a wafer is lower than the temperature of a center portion. Then, it was found that by forming an unevenness at a predetermined position of a back surface of a susceptor on which a wafer is placed, the effective emissivity of the portion can be increased and thus a heat input amount is increased, thereby it is possible to suppress a decrease in temperature and uniformize a temperature distribution during epitaxial growth.

That is, the present invention provides the following apparatus in order to solve the above problems.

(1) A SiC epitaxial growth apparatus of the first aspect includes: a susceptor having a mounting surface on which a wafer is placable; and a heater which is provided apart from the susceptor on a side opposite to the mounting surface of the susceptor, wherein an unevenness is formed on a radiation-receiving surface of the susceptor, which faces a first surface of the heater provided at the susceptor side, and the unevenness is located at a position which is overlapped with an outer peripheral portion of the wafer placed on the susceptor in a plan view.

The apparatus of the first aspect preferably includes the following features. The following features are preferably combined with each other.

(2) In the SiC epitaxial growth apparatus according to the aspect, the heater and the wafer placed on the susceptor may be disposed concentrically with each other, and a radial distance between an outer peripheral end of the heater and an outer peripheral end of the wafer placed on the susceptor may be 1/12 or less of a diameter of the wafer in the plan view.

(3) In the SiC epitaxial growth apparatus according to the aspect, when an actual surface area of a portion where the unevenness is formed is expressed by S₁ and an area of a flat surface wherein the portion where the unevenness is formed is assumed to be a flat surface is expressed by S₀, an area ratio (S₁/S₀) may be 2 or more.

(4) In the SiC epitaxial growth apparatus according to the aspect, the unevenness may be constituted by a plurality of recessed portions which are recessed with respect to a reference surface, and an aspect ratio of the recessed portion may be 1 or more.

(5) In the SiC epitaxial growth apparatus according to the aspect, the susceptor may include a radiation member, and the radiation member may be provided on a back surface of the susceptor at the position which is overlapped with the outer peripheral portion of the wafer placed on the susceptor in the plan view, and one surface of the radiation member located at the heater side may have the unevenness.

(6) The SiC epitaxial growth apparatus according to the aspect may further include: a center supporting element which supports a center portion of the susceptor from a back surface of the susceptor which is opposite to the mounting surface.

(7) In the SiC epitaxial growth apparatus according to the aspect, a radial width of a portion where the unevenness is formed may be 1/25 or more and 6/25 or less of a radius of the wafer which is placable on the susceptor.

(8) The SiC epitaxial growth apparatus according to the aspect may further include: an outer periphery supporting element which supports an outer peripheral end portion of the susceptor from a back surface of the susceptor which is opposite to the mounting surface.

(9) In the SiC epitaxial growth apparatus according to the aspect, a radial width of a portion where the unevenness is formed may be 1/50 or more and ⅕ or less of a radius of the wafer which is placable on the susceptor.

### Effects of Invention

With the SiC epitaxial growth apparatus according to the first aspect of the present invention, it is possible to uniformize a temperature distribution during epitaxial growth.

### BRIEF DESCRIPTION OF THE DRAWINGS

FIG. 1 is a schematic sectional view illustrating a preferable example of a SiC epitaxial growth apparatus according to a first embodiment.

FIG. 2 is an enlarged schematic sectional view of a main part of the SiC epitaxial growth apparatus according to the first embodiment shown in FIG. 1.

FIG. 3A is a plan view of a preferable example of recessed portions formed on a radiation-receiving surface.

FIG. 3B is a plan view of a preferable example of the recessed portions formed on the radiation-receiving surface.

FIG. 3C is a plan view of a preferable example of the recessed portions formed on the radiation-receiving surface.

FIG. 3D is a plan view of a preferable example of the recessed portions formed on the radiation-receiving surface.

FIG. 4 is a schematic view of another preferable example of the SiC epitaxial growth apparatus according to the first embodiment, in which a susceptor includes a radiation member and the radiation member is positioned at a back surface side of the susceptor.

FIG. 5 is a schematic view of another preferable example of the SiC epitaxial growth apparatus according to the first embodiment, in which the susceptor includes the radiation member and the radiation member is engaged with the back surface of the susceptor.

FIG. 6 is a schematic sectional view illustrating a preferable example of a SiC epitaxial growth apparatus according to a second embodiment, and is an enlarged view of a main part of the apparatus.

FIG. 7 is a schematic sectional view illustrating another preferable example of the SiC epitaxial growth apparatus according to the second embodiment, in which the susceptor includes the radiation member and the radiation member is positioned at the back surface side of the susceptor.

FIG. 8 is a schematic sectional view illustrating another preferable example of the SiC epitaxial growth apparatus according to the second embodiment, in which the susceptor includes the radiation member and the radiation member is held between the susceptor and an outer periphery supporting element.

FIG. 9 is a diagram showing temperature distributions of the surface of wafers in Examples 1 to 3 and Comparative Example 1.

FIG. 10 is a diagram showing temperature distributions of the surface of wafers in Example 4 and Comparative Example 1.

FIG. 11 is a diagram showing temperature distributions of the surface of wafers in Examples 5 to 7 and Comparative Example 2.

FIG. 12 is a diagram showing temperature distributions of the surface of wafers in Example 8 and Comparative Example 2.

### DETAILED DESCRIPTION OF THE INVENTION

Hereinafter, a SiC epitaxial growth apparatus according to the embodiments will be described in detail with reference to the drawings as appropriate. In the drawings used in the following description, for ease of understanding of the features of the present invention, there are cases where characteristic portions are enlarged for convenience, and dimensions, ratios and the like of each constituent element may be the same as or may be different from actual sizes and the like. The materials, dimensions, and the like shown in the following description are merely examples, and the present invention is not limited thereto and can be embodied in appropriately modified manners in a range that does not change the gist thereof.

### First Embodiment

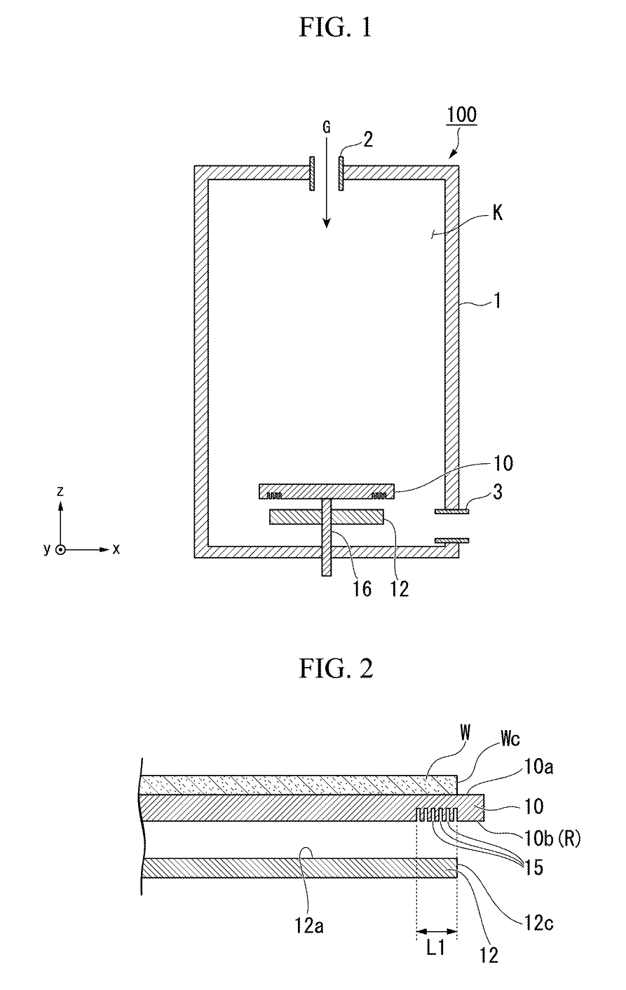

FIG. 1 is a schematic sectional view of a SiC epitaxial growth apparatus 100 according to a first embodiment. The SiC epitaxial growth apparatus 100 illustrated in FIG. 1 includes a chamber 1 which forms a film formation space K. The chamber 1 includes a gas supply port 2 through which gas is supplied, and a gas discharge port 3 through which the gas is discharged. In the film formation space K, a susceptor 10, and a heater 12 are provided.

In addition, the susceptor 10 is supported by a center supporting element 16. Hereinafter, a direction perpendicular to a mounting surface of the susceptor 10 is referred to as a z direction, and optionally selected two directions which are orthogonal to each other on the mounting surface are referred to as an x direction and a y direction.

FIG. 2 is an enlarged schematic sectional view of a main part of the SiC epitaxial growth apparatus 100. In FIG. 2, for ease of understanding, a disk-shaped wafer W, which is not a constituent member of the apparatus, is also illustrated.

The wafer W can be placed on a mounting surface 10a of the susceptor 10. Any known susceptor can be used as the susceptor 10. The susceptor 10 may have a circular shape in a plan view. The susceptor 10 is formed of a material which has heat resistance at a high temperature exceeding 1500° C. and has low reactivity with a raw material gas. For example, Ta, TaC, carbon coated with TaC, Ta coated with TaC, and graphite can be used. In a film formation temperature region, the emissivity of TaC and carbon coated with TaC is about 0.2 to 0.3, and the emissivity of graphite is about 0.7.

The heater 12 is provided apart from the susceptor 10 at a back surface 10b side of the susceptor 10, which is opposite to the mounting surface 10a. Any known heater can be used as the heater 12. The heater 12 may have a circular shape in a plan view. It is preferable that the heater 12 is disposed concentrically with the susceptor 10 and the wafer W in the plan view observed from the z direction. By disposing the heater 12 concentrically with the susceptor 10 and the wafer W on the same center axis, the thermal uniformity of the wafer W can be enhanced.

It is preferable that the radial distance between an outer peripheral end 12c of the heater 12 and an outer peripheral end Wc of the wafer W is equal to or less than 1/12 of the diameter of the wafer W, and more preferably equal to or less than 1/20. Furthermore, it is more preferable that the outer peripheral end 12c of the heater 12 and the outer peripheral end Wc of the wafer W coincide in the plan view observed from the z direction. When the radial size of the heater 12 is smaller than that of the wafer W, the thermal uniformity of the surface temperature of the wafer W decreases. In addition, when the radial size of the heater 12 is larger than that of the wafer W, the heater 12 protrudes in a radially outward direction in the plan view observed from the z direction, resulting in an increase in the size of the SiC epitaxial growth apparatus 100. An increase in the size of the apparatus results in an increase in cost and is thus undesirable.

In the SiC epitaxial growth apparatus 100, an unevenness is formed on a radiation-receiving surface R of the susceptor, which faces a first surface 12a of the heater 12 which is located on the side where the susceptor 10 is provided. The radiation-receiving surface R is an outermost surface which faces the first surface 12a of the heater 12 located on the susceptor 10 side, and is a surface directly receiving radiation from the heater 12.

In FIG. 2, the back surface 10b of the susceptor 10 corresponds to the radiation-receiving surface R. The unevenness in FIG. 2 is constituted by a plurality of recessed portions 15 which are recessed with respect to a reference surface. The plurality of recessed portions 15 (valley portions) may be provided between a plurality of protruding portions (hill portions or projecting portions). The reference surface is a surface which is parallel to an xy plane and is passing through the surface (the back surface 10b) of the susceptor 10 which is closest to the heater 12.

The unevenness is located at a position which is overlapped with the outer peripheral portion of the wafer W in the plan view observed from the z direction. Here, the outer peripheral portion of the wafer W means a circular region which has a width of 10% of the diameter of the wafer and is located from the outer peripheral end Wc of the wafer W toward the inside. The portion where the unevenness is formed and the outer peripheral portion of the wafer W may at least partially overlap each other in the plan view observed from the z direction.

When the unevenness is formed on the radiation-receiving surface R, an effective emissivity of the portion where the unevenness is formed increases. This is because the area that can absorb radiation (radiant heat) sent from the heater 12 is widened due to the unevenness. The emissivity is equivalent to heat absorption rate, and the absorptivity of the portion increases as the effective emissivity increases. When the unevenness of the susceptor which has a high effective emissivity is located at the outer peripheral side of the wafer W, the uneven portion efficiently absorbs radiant heat radiated from the heater 12. As a result, it is possible to suppress a decrease in the temperature of the outer peripheral portion of the wafer W compared to the center portion of the wafer.

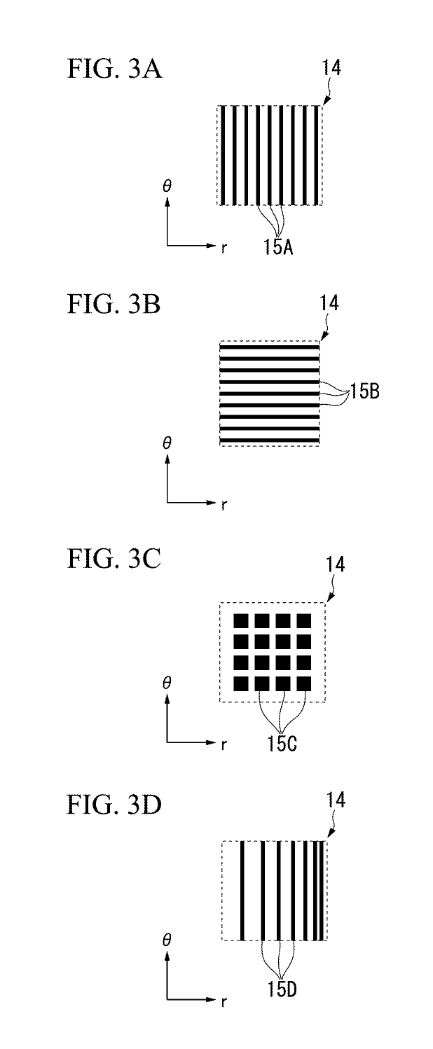

FIGS. 3A to 3D are schematic views of the radiation-receiving surface R in the plan view. The recessed portion 15 may have annular shape in the plan view, and portions indicated by parallel straight lines in these figures may be curved and/or may not be parallel to each other. Among the directions indicated in the coordinates shown in FIGS. 3A to 3D, the r direction is the radial direction, and the θ direction is a circumferential direction. As in the examples illustrated in FIGS. 3A to 3D, the shape of the recessed portion 15 is not particularly limited. For example, recessed portions 15A illustrated in FIG. 3A are formed concentrically. Recessed portions 15B illustrated in FIG. 3B are formed such that they extend radially from the center of the susceptor. In recessed portions 15C illustrated in FIG. 3C, the recessed portions are dotted in the circumferential direction and the radial direction. Recessed portions 15D illustrated in FIG. 3D are formed concentrically such that the interval therebetween decreases toward the outer circumference. When the interval between the recessed portions 15D decreases toward the outer peripheral side, the temperature of the outer peripheral end portion can be efficiently increased. The unevenness is not limited to that of the recessed portions 15 which is recessed with respect to the reference surface, and may be unevenness having a randomly formed uneven surface.

When the actual surface area of the portion where the unevenness is formed (the area including the side surface and the bottom surface of the recessed portion) is expressed by S₁ and the area of a flat surface wherein the portion where the unevenness is formed is assumed to be a flat surface (the area of the flat surface) is expressed by S₀, the area ratio (S₁/S₀) is preferably 2 or more, more preferably 8 or more, and more preferably 16 or more. In addition, the area ratio (S₁/S₀) is preferably 20 or less. Here, the portion where the unevenness is formed means a region provided between a circumscribed circle circumscribed to the portion where the unevenness is formed and an inscribed circle inscribed to the portion.

A relationship represented by General Formula (1) shown below is established between the area ratio and the effective emissivity. Therefore, when the area ratio (S₁/S₀) satisfies the above condition, the effective emissivity of the portion where the unevenness is formed can be sufficiently increased. For example, in a case where the emissivity s intrinsic to the material is 0.2 and the area ratio (S₁/S₀) is 2.0, the effective emissivity becomes 0.33.

$$\begin{matrix}Formula 1 & \\ {ɛ}_{e} = \frac{ɛ}{ɛ + ( \frac{{S}_{0}}{{S}_{1}} ) ( 1 - ɛ )} & ( 1 )\end{matrix}$$

Furthermore, as illustrated in FIG. 1, in a case where the unevenness is constituted by the plurality of recessed portions 15 which are recessed with respect to the reference surface, the aspect ratio of the recessed portion 15 (the depth of the recessed portion/the width of the recessed portion in the plan view) is preferably 1 or more, and more preferably 5 or more. In addition, the aspect ratio is preferably 20 or less. When the aspect ratio of the recessed portion 15 is large, radiation which enters in the recessed portion 15 cannot escape from the recessed portion 15, so that the heat absorption efficiency can be further increased. For example, in a case where the aspect ratio is 1, 80% of the radiation entered in the recessed portion 15 can be used, and in a case where the aspect ratio is 10, 90% or more of the radiation entered in the recessed portion 15 can be used.

The shape and conditions of the recessed portion 15 can be optionally selected. The depth of the recessed portion 15 is preferably 0.01 mm or more, and more preferably 1 mm or more. The depth of the recessed portion is preferably 3 mm or less.

The width of the recessed portion 15 is preferably 3 mm or less, and more preferably 0.2 mm or less. The width of the recessed portion is preferably 0.01 mm or more.

The interval between the recessed portions 15 is preferably 3 mm or less, and more preferably 0.2 mm or less. The interval between the recessed portions is preferably 0.01 mm or more. Here, the interval between the recessed portions 15 means the distance between the centers of the adjacent recessed portions 15 in the radial direction.

A radial width L1 of the portion where the unevenness is formed can be optionally selected, but is preferably 1/25 or more and 6/25 or less of the radius of the wafer W which can be placed on the susceptor 10. When the radial width L1 of the portion where the unevenness is formed is in the above range, the temperature of the wafer W can be made more uniform in an in-plane direction.

In the SiC epitaxial growth apparatus, the susceptor may include a radiation member. The radiation member 14 may be provided on the back surface 10b of the susceptor 10 at a position which is overlapped with the outer peripheral portion of the wafer W placed on the susceptor 10 in the plan view. The radiation member may have an annular shape in the plan view. The SiC epitaxial growth apparatus may not include radiation member. However, by including the radiation member, temperature control can be performed more efficiently.

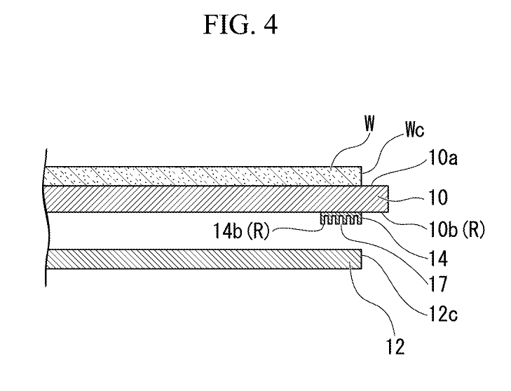

FIG. 4 is a schematic view of a SiC epitaxial growth apparatus having the radiation member on the back surface side of the susceptor, which is another example of the SiC epitaxial growth apparatus according to the first embodiment. In a case where the susceptor has the radiation member 14, the back surface 10b (exposed portion) of the main body of the susceptor 10 and one surface 14b of the radiation member 14 located on the heater 12 side correspond to the radiation-receiving surface R. An unevenness is formed on the surface 14b of the radiation member 14 by a plurality of recessed portions 17 provided on the reference surface.

The radiation member 14 is formed of a material which has a higher emissivity than the susceptor 10 as the main body. The emissivity of the radiation member 14 is preferably 1.5 times or more and 7 times or less of the emissivity of the susceptor 10. For example, in a case where the susceptor 10 is formed from carbon coated with TaC (emissivity: 0.2), graphite (emissivity: 0.7), carbon coated with SiC (emissivity: 0.8), SiC (emissivity: 0.8) or the like is used as the radiation member 14. As the emissivity, a value of emissivity may be obtained from a literature in which an emissivity table is described, or the emissivity may be obtained by conducting an experiment.

The radiation member 14 is in contact with the back surface 10b of the susceptor 10 such that a portion of the radiation member is exposed to the space, when viewed from the side where the heater 12 is provided. Since the portion of the radiation member 14 is exposed, radiant heat generated from the heater 12 can be efficiently absorbed in the radiation member. The other portion of the radiation member 14 which is not exposed to the space is in contact with the susceptor 10 directly or via an adhesive or the like. Furthermore, since the upper surface of the radiation member 14 is in contact with the back surface 10b of the susceptor 10, the temperature of the outer peripheral portion of the wafer W can be increased due to thermal conduction. In a case where the radiation member 14 is not in contact with the back surface 10b of the susceptor 10, the temperature of the outer peripheral portion cannot be sufficiently increased. It is considered that this is because the radiation member 14 shields a part of radiation emitted toward the back surface 10b of the susceptor 10 and thus the heat absorption efficiency decreases. In addition, it is also considered that this is because heat absorbed by the radiation member 14 cannot be efficiently transferred to the susceptor 10 when the susceptor 10 and the radiation member 14 are not in contact with each other.

The radiation member 14 may be bonded to the back surface 10b of the susceptor 10 or may be engaged with the susceptor 10.

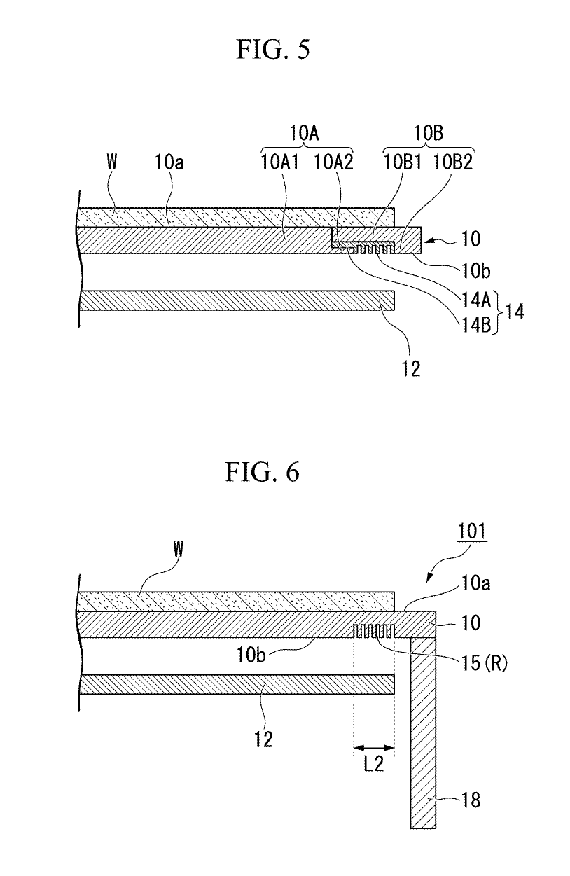

FIG. 5 is an enlarged schematic view of a main part of the SiC epitaxial growth apparatus according to the first embodiment in an example in which the radiation member 14 is engaged with the susceptor 10.

The susceptor 10 illustrated in FIG. 5 is constituted by a first member 10A and a second member 10B. The first member 10A includes a main portion 10A1 and a protruding portion 10A2. The protruding portion 10A2 protrudes from the main portion 10A1 in the radial direction (x direction). The second member 10B includes a main portion 10B1 and a protruding portion 10B2. The protruding portion 10B2 protrudes from the main portion 10B1 in the z direction. The first member 10A and the second member 10B are preferably formed using the same material.

The radiation member 14 is also constituted by a first portion 14A and a second portion 14B. The first portion 14A is a main portion of the radiation member 14, and the second portion 14B extends from the first portion 14A in the radial direction. The second portion 14B of the radiation member 14 is engaged into a gap provided between the protruding portion 10A2 of the first member 10A and the main portion 10B1 of the second member 10B. A lower portion of the first portion 14A of the radiation member 14 is sandwiched between the protruding portion 10A2 of the first member 10A and the protruding portion 10B2 of the second member 10B. The radiation member 14 is supported by the susceptor 10 by its own weight of the radiation member 14. In this case, the radial width of the radiation member 14 means a width of a portion of the radiation member 14 which is exposed to the back surface 10b side of the susceptor 10. When the radiation member 14 and the susceptor 10 can be joined together without using an adhesive, adhesive is not required. Although it is possible to use an adhesive for them, there are cases where peeling of the adhesive occurs due to stress which occurs by a difference of linear thermal expansion coefficient thereof. Therefore, it is desirable that the radiation member 14 is fixed by a method which does not use an adhesive. Due to the supporting structure described above, an adhesive may be used or may not be used between the radiation member 14 and the susceptor 10.

The center supporting element 16 supports the center of the susceptor 10 from the back surface 10b side of the susceptor 10.

The center supporting element 16 is formed of a material having heat resistance to an epitaxial growth temperature. The center supporting element 16 may also be rotatable as a shaft extending from the center of the susceptor in the z direction. Epitaxial growth can be performed while rotating the wafer W by rotating the center supporting element 16.

As described above, in the SiC epitaxial growth apparatus 100 according to the first embodiment, the unevenness is formed on the radiation-receiving surface R facing the first surface 12a of the heater 12 which is provided at the susceptor 10 side. With such a configuration, it is possible to increase the effective emissivity of the uneven portion and suppress a decrease in the temperature of the outer peripheral portion of the wafer W.

### Second Embodiment

FIG. 6 is an enlarged schematic sectional view of a main part of a SiC epitaxial growth apparatus 101 according to a second embodiment. The SiC epitaxial growth apparatus 101 according to the second embodiment is different from that of the first embodiment only in that the susceptor 10 is supported not by the center supporting element 16 but by an outer periphery supporting element 18. The other configurations are almost the same as those of the SiC epitaxial growth apparatus 100 according to the first embodiment, and same configurations are denoted by the same reference numerals and the description thereof will be omitted. The heater may be supported by the center supporting element that supports the heater at the center portion. The outer periphery supporting element 18 may have a circular shape.

The outer periphery supporting element 18 supports the outer circumference portion of the susceptor 10 from the back surface 10b side of the susceptor 10.

The outer periphery supporting element 18 can be formed of the same material as that of the center supporting element 16.

In the SiC epitaxial growth apparatus 101 according to the second embodiment, an unevenness is formed on the radiation-receiving surface R of the susceptor facing the first surface 12a of the heater 12 which is located on the susceptor 10 side. In FIG. 6, the unevenness is constituted by the plurality of recessed portions 15 which are recessed with respect to the reference surface.

A preferable range of a radial width L2 of the portion where the unevenness is formed in this apparatus is different from that in the SiC epitaxial growth apparatus 100 according to the first embodiment. The reason is that the susceptor 10 is supported by the outer periphery supporting element 18 and thus the outer periphery supporting element 18 also receives radiation from the heater.

In a case where the susceptor 10 is supported by the outer periphery supporting element 18, the radial width L2 of the portion where the unevenness is formed is preferably 1/50 or more and ⅕ or less of the radius of the wafer W. As necessary, the ratio may be 1/50 or more and less than 1/20, 1/20 or more and less than 1/10, or 1/10 or more and ⅕ or less. When the radial width L2 of the portion where the unevenness is formed is within the above range, the temperature of the wafer W in the in-plane direction can be made more uniform. The outer periphery supporting element 18 receives radiation from the heater 12 and generates heat. Therefore, compared to the case where the susceptor 10 is supported by the center supporting element 16, the radial width L2 of the portion where the unevenness is formed can be reduced.

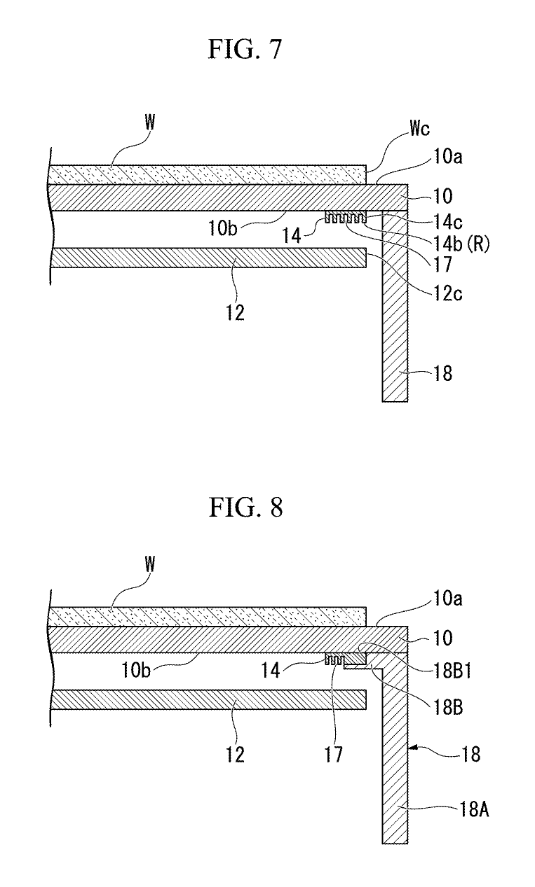

FIG. 7 illustrates another example of the SiC epitaxial growth apparatus according to the second embodiment. FIG. 7 is a schematic view of the SiC epitaxial growth apparatus in which the susceptor has the radiation member 14 and the radiation member 14 is provided on the back surface 10b of the susceptor 10 as the main body. An unevenness is formed on a surface 14b (lower surface) of the radiation member 14 by providing the plurality of recessed portions 17 to the reference surface. As the radiation member 14, the same radiation member as in the SiC epitaxial growth apparatus 100 according to the first embodiment can be used.

FIG. 8 illustrates another example of the SiC epitaxial growth apparatus according to the second embodiment. FIG. 8 is a schematic view of the SiC epitaxial growth apparatus in which the susceptor includes the radiation member 14 and the radiation member 14 is held between the susceptor 10 as the main body and the outer periphery supporting element 18.

The outer periphery supporting element 18 illustrated in FIG. 8 has a support column 18A and a protruding portion 18B. The support column 18A is a portion extending in the z direction and is a main portion of the outer periphery supporting element 18. The protruding portion 18B is a portion protruding from the support column 18A in the in-plane direction. The protruding portion 18B is provided with a fitting groove 18B1.

When the susceptor 10 is supported by the outer periphery supporting element 18, a gap is formed between the outer periphery supporting element 18 and the susceptor 10 due to the fitting groove 18B1. By inserting the radiation member 14 into the gap, the radiation member 14 is supported between the susceptor 10 and the outer periphery supporting element 18 by its own weight. The recessed portions 17 are formed on the surface of the radiation member 14 which is exposed to the side where the heater 12 is provided. Since the radiation member 14 can be supported by its own weight, an adhesive may be used or may not be used for the radiation member 14.

As described above, according to the SiC epitaxial growth apparatus 101 of the second embodiment, the thermal uniformity of the wafer W in the in-plane direction can be enhanced. This is because the unevenness is formed on the radiation-receiving surface R and thus the effective emissivity of the portion increases.

While the preferred embodiments of the present invention have been described above in detail, the present invention is not limited to the specific embodiments, and various changes and modifications may be made without departing from the scope of the present invention described in the claims.

### EXAMPLES

### Example 1

A temperature state of the surface of a wafer, which is observed when the SiC epitaxial growth apparatus having the configuration illustrated in FIG. 2 is used, was obtained by a simulation. For the simulation, ANSYS Mechanical (manufactured by ANSYS Co., Ltd.) which is a general-purpose thermal analysis software was used.

For the simulation conditions, the emissivity of the susceptor 10 was set to 0.2 (corresponding to that of carbon coated with TaC). The plurality of recessed portions 15 were provided concentrically on the back surface 10b of the susceptor 10. The position of the outer peripheral end of the plurality of recessed portions 15 was allowed to coincide with the positions of the outer peripheral end of the wafer W and the outer peripheral end of the heater 12. The groove width and the groove interval of the plurality of recessed portions 15 were set to 0.2 mm, and the depth thereof was set to 1.0 mm. The width between the outer peripheral end and the inner peripheral end of the plurality of recessed portions 15 (the width L1 of the portion where the unevenness is formed) was set to 12 mm. The radius of the wafer was set to 100 mm. The in-plane distribution of the surface temperature of the wafer was obtained based on the above conditions.

### Example 2

Example 2 is different from Example 1 in that the width L1 of the portion where the unevenness is formed was set to 4 mm. The other conditions were the same as in Example 1.

### Example 3

Example 3 is different from Example 1 in that the width L1 of the portion where the unevenness is formed was set to 24 mm.

The other conditions were the same as in Example 1.

### Comparative Example 1

Comparative Example 1 is different from Example 1 in that no unevenness was provided on the radiation-receiving surface R. The other conditions were the same as in Example 1.

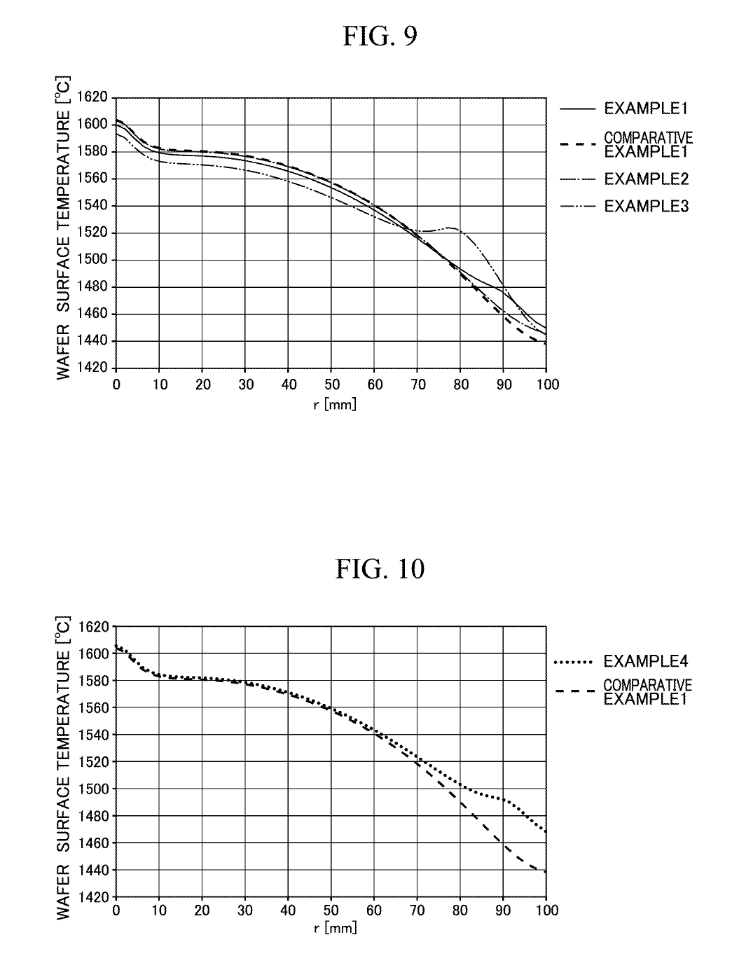

FIG. 9 is a diagram showing temperature distributions of the surface of wafers of Examples 1 to 3 and Comparative Example 1. The horizontal axis represents the radial position of the wafer from the center, and the vertical axis represents the surface temperature of the wafer at the position of the wafer. As shown in FIG. 9, by providing the unevenness on the radiation-receiving surface R, a decrease in the temperature of the wafer at the outer peripheral side was suppressed.

### Example 4

In Example 4, a simulation was performed using the SiC epitaxial growth apparatus having the configuration illustrated in FIG. 4. That is, the radiation member 14 was provided on the back surface 10b of the susceptor 10. In addition, the plurality of recessed portions 17 were provided on the surface 14b of the radiation member 14. The position of the outer peripheral end of the radiation member 14 was allowed to coincide with the positions of the outer peripheral end of the wafer W and the outer peripheral end of the heater 12. The width of the outer peripheral end and the inner peripheral end of the radiation member 14 was set to 10 mm. The plurality of recessed portions 17 were arranged concentrically on the entire surface of the surface 14b of the radiation member 14. The groove width and the groove interval of the plurality of recessed portions 17 were set to 0.2 mm, and the depth thereof was set to 1.0 mm. The in-plane distribution of the surface temperature of the wafer was measured based on the above conditions.

FIG. 10 is a diagram showing temperature distributions of the surface of wafers of Example 4 and Comparative Example 1. The horizontal axis represents the radial position of the wafer from the center, and the vertical axis represents the surface temperature of the wafer at the position. As shown in FIG. 10, by providing the uneven shape on the radiation-receiving surface R of the radiation member 14 and using the radiation member 14 having a small emissivity, a decrease in the temperature of the wafer at the outer peripheral side was suppressed.

Table 1 summarizes the results of the investigation. An in-plane temperature difference dT means the temperature difference between the maximum value and the minimum value of the temperature in the surface of the wafer.

TABLE 1

| | Exam- | | Exam- | | Comparative |
|---|---|---|---|---|---|
| | ple 1 | Example 2 | ple 3 | Example 4 | Example 1 |
| Width of | 0.2 | 0.2 | 0.2 | 0.2 | — |
| recessed | | | | | |
| portion | | | | | |
| (mm) | | | | | |
| Interval | 0.2 | 0.2 | 0.2 | 0.2 | — |
| between | | | | | |
| recessed | | | | | |
| portions | | | | | |
| (mm) | | | | | |
| Depth of | 1.0 | 1.0 | 1.0 | 1.0 | — |
| recessed | | | | | |
| portion | | | | | |
| (mm) | | | | | |
| Aspect ratio of | 5.0 | 5.0 | 5.0 | 5.0 | — |
| recessed | | | | | |
| portion | | | | | |
| Width L1 of | 12 | 4 | 24 | 10 | |
| portion having | | | | | |
| unevenness | | | | | |
| (mm) | | | | | |
| Presence or | Absent | Absent | Absent | Present | Absent |
| absence of | | | | | |
| radiation | | | | | |
| member | | | | | |
| Apparatus | FIG. 2 | FIG. 2 | FIG. 2 | FIG. 4 | — |
| configuration | | | | | |
| In-plane | 150.3 | 157.9 | 148.6 | 137.5 | 165.8 |
| temperature | | | | | |
| difference dT | | | | | |
| (° C.) | | | | | |

### Example 5

A temperature state of the surface of wafers, which is obtained when the SiC epitaxial growth apparatus having the configuration illustrated in FIG. 6 was used, was obtained by a simulation. The same method as in Example 1 was used for the simulation.

For the simulation conditions, the emissivity of the susceptor 10 was set to 0.2 (corresponding to that of carbon coated with TaC). The plurality of recessed portions 15 were provided concentrically on the back surface 10b of the susceptor 10. The position of the outer peripheral end of the plurality of recessed portions 15 was allowed to coincide with the positions of the outer peripheral end of the wafer W and the outer peripheral end of the heater 12. The groove width and the groove interval of the plurality of recessed portions 15 were set to 0.5 mm, and the depth thereof was set to 0.5 mm. The width between the outer peripheral end and the inner peripheral end of the plurality of recessed portions 15 (the width L2 of the portion where the unevenness is formed) was set to 10 mm. The in-plane distribution of the surface temperature of the wafer was measured based on the above conditions.

### Example 6

Example 6 is different from Example 5 in that the width L2 of the portion where the unevenness is formed was set to 2 mm. The other conditions were the same as in Example 5.

### Example 7

Example 7 is different from Example 5 in that the width L2 of the portion where the unevenness is formed was set to 20 mm.

The other conditions were the same as in Example 5.

### Comparative Example 2

Comparative Example 2 is different from Example 5 in that no unevenness was provided on the radiation-receiving surface R. The other conditions were the same as in Example 2.

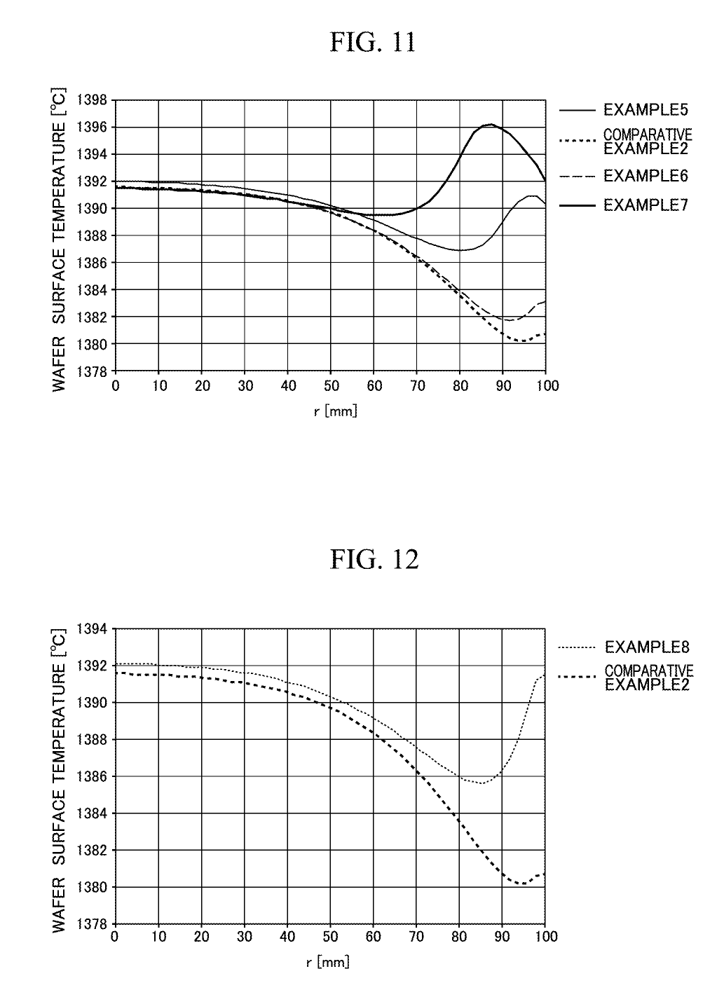

FIG. 11 is a diagram showing temperature distributions of the surface of wafers of Examples 5 to 7 and Comparative Example 2. The horizontal axis represents the radial position of the wafer from the center, and the vertical axis represents the surface temperature of the wafer at the position.

As shown in FIG. 11, by providing the unevenness on the radiation-receiving surface R, a decrease in the temperature of the wafer from the outer peripheral side was suppressed.

### Example 8

In Example 8, a simulation was performed using the SiC epitaxial growth apparatus having the configuration illustrated in FIG. 7. That is, the radiation member 14 was provided on the back surface 10b of the susceptor 10. In addition, the plurality of recessed portions 17 were provided on the surface 14b of the radiation member 14. The position of the outer peripheral end of the radiation member 14 was allowed to coincide with the positions of the outer peripheral end of the wafer W and the outer peripheral end of the heater 12. The width of the outer peripheral end and the inner peripheral end of the radiation member 14 was set to 2 mm The plurality of recessed portions 17 were arranged concentrically on the entire surface of the surface 14b of the radiation member 14. The groove width and the groove interval of the plurality of recessed portions 17 were set to 0.5 mm, and the depth thereof was set to 0.5 mm.

The in-plane distribution of the surface temperature of the wafer was measured based on the above conditions.

FIG. 12 is a diagram showing temperature distributions of the surface of wafers of Example 8 and Comparative Example 2. The horizontal axis represents the radial position of the wafer from the center, and the vertical axis represents the surface temperature of the wafer at the position. As shown in FIG. 12, by providing the uneven shape on the radiation-receiving surface R of the radiation member 14 and using the radiation member 14 having a small emissivity, a decrease in the temperature of the wafer at the outer peripheral side was suppressed.

Table 2 summarizes the results of the investigation.

TABLE 2

| | Exam- | Exam- | Exam- | | Comparative |
|---|---|---|---|---|---|
| | ple 5 | ple 6 | ple 7 | Example 8 | Example 2 |
| Width of | 0.5 | 0.5 | 0.5 | 0.5 | — |
| recessed portion | | | | | |
| (mm) | | | | | |
| Interval | 0.5 | 0.5 | 0.5 | 0.5 | — |
| between | | | | | |
| recessed | | | | | |
| portions | | | | | |
| (mm) | | | | | |
| Depth of | 0.5 | 0.5 | 0.5 | 0.5 | — |
| recessed portion | | | | | |
| (mm) | | | | | |
| Aspect ratio of | 1.0 | 1.0 | 1.0 | 1.0 | — |
| recessed portion | | | | | |
| Width L2 of | 10 | 2 | 20 | — | — |
| portion having | | | | | |
| unevenness | | | | | |
| (mm) | | | | | |
| Presence or | Absent | Absent | Absent | Present | Absent |
| absence of | | | | | |
| radiation | | | | | |
| member | | | | | |
| Apparatus | FIG. 6 | FIG. 6 | FIG. 6 | FIG. 7 | — |
| configuration | | | | | |
| In-plane | 5.1 | 9.8 | 6.7 | 6.5 | 11.4 |
| temperature | | | | | |
| difference dT | | | | | |
| (° C.) | | | | | |

As described above, according to the present invention, it is possible to obtain a SiC epitaxial growth apparatus capable of uniformizing a temperature distribution during epitaxial growth.

### EXPLANATION OF REFERENCES

1: chamber

2: gas supply port

3: gas discharge port

10: susceptor

10a: mounting surface

10b: back surface

10A: first member

10A1: main portion

10A2: protruding portion

10B: second member

10B1: main portion

10B2: protruding portion

12: heater

12a: first surface of heater on susceptor side

12c: outer peripheral end of heater

14: radiation member

14A: first portion

14B: second portion

14b: one surface

14c: outer peripheral end of radiation member

15, 15A, 15B, 15C, 15D: recessed portion provided in main body of susceptor

16: center supporting element

17: recessed portion of radiation member

18: outer periphery supporting element

18A: support column

18B: protruding portion

18B1: fitting groove

100, 101: SiC epitaxial growth apparatus

W: wafer

Wc: outer peripheral end of wafer

K: film formation space

R: radiation-receiving surface

L1, L2: width of portion where unevenness is formed

G: gas

1. A SiC epitaxial growth apparatus comprising:
a susceptor having a mounting surface on which a wafer is placable; and
a heater which is provided apart from the susceptor on a side opposite to the mounting surface of the susceptor,
wherein an unevenness is formed on a radiation-receiving surface of the susceptor, which faces a first surface of the heater provided at the susceptor side, and the unevenness is located at a position which is overlapped with an outer peripheral portion of the wafer placed on the susceptor in a plan view.

2. The SiC epitaxial growth apparatus according to claim 1,
wherein the heater and the wafer placed on the susceptor are disposed concentrically with each other, and a radial distance between an outer peripheral end of the heater and an outer peripheral end of the wafer placed on the susceptor is 1/12 or less of a diameter of the wafer in the plan view.

3. The SiC epitaxial growth apparatus according to claim 1,
wherein when an actual surface area of a portion where the unevenness is formed is expressed by S₁ and an area of a flat surface wherein the portion where the unevenness is formed is assumed to be a flat surface is expressed by S₀, an area ratio (S₁/S₀) is 2 or more.

4. The SiC epitaxial growth apparatus according to claim 1,
wherein the unevenness is constituted by a plurality of recessed portions which are recessed with respect to a reference surface, and an aspect ratio of the recessed portion is 1 or more.

5. The SiC epitaxial growth apparatus according to claim 1,
wherein the susceptor comprises a radiation member, and the radiation member is provided on a back surface of the susceptor at the position which is overlapped with the outer peripheral portion of the wafer placed on the susceptor in the plan view, and
a surface of the radiation member located at the heater side has the unevenness.

6. The SiC epitaxial growth apparatus according to claim 1, further comprising:
a center supporting element which supports a center portion of the susceptor from a back surface of the susceptor which is opposite to the mounting surface.

7. The SiC epitaxial growth apparatus according to claim 6,
wherein a radial width of a portion where the unevenness is formed is 1/25 or more and 6/25 or less of a radius of the wafer which is placable on the susceptor.

8. The SiC epitaxial growth apparatus according to claim 1, further comprising:
an outer periphery supporting element which supports an outer peripheral end portion of the susceptor from a back surface of the susceptor which is opposite to the mounting surface.

9. The SiC epitaxial growth apparatus according to claim 8,
wherein a radial width of a portion where the unevenness is formed is 1/50 or more and ⅕ or less of a radius of the wafer which is placable on the susceptor.
